(19) United States
(12) Patent Application Publication
(10) Pub. No.: US 2003/0011354 A1
(43) Pub. Date: Jan. 16, 2003

(54) Grounding clamp with high voltage detection device

(76) Inventor: Lee Randolph Daniel, Battleboro, NC (US)

Correspondence Address: The Law Office of Clifford F. Rey, 853-I Wake Forest Business Park, P.O. 1555, Wake Forest, NC, 27588-1555, US

(21) Appl. No.: 09/901,965

(22) Filed: Jul. 11, 2001

(51) Int. Cl. G01R 33/00

(52) U.S. Cl. 324/117 R

(57) ABSTRACT

A high voltage detection device for use in combination with a manually-operated grounding clamp and other hand tools utilized by electrical utility personnel during maintenance of high voltage power lines and other industrial equipment is disclosed. The present invention modifies the conventional grounding clamp and other hand tools by integrating a high voltage detection device therein to produce an audible alarm signal whenever the grounding clamp and other tools come into close proximity with a source of high voltage. In one embodiment the voltage detection device comprises a cylindrical housing containing a voltage sensor of the type capable of detecting the magnetic field generated by the flow of electrical current in a specific voltage range. If a magnetic field associated with high voltage is detected, the sensor generates a signal that is transmitted to a microprocessor within the housing being programmed to process the signal and to actuate a miniature speaker, which produces an audible alarm in advance of the impending contact.

### BACKGROUND OF INVENTION

Field of Invention

The present invention relates to voltage detection devices and, more particularly, to a high voltage detection device in combination with a grounding clamp or other hand tools utilized by electrical utility line workers during maintenance of high voltage power lines and other industrial equipment.

Voltage detection devices capable of detecting a magnetic field generated by the flow of electrical current are well known to those skilled in the art. For example, voltage detection devices are employed on various utility vehicles, which carry telescoping masts, booms, and/or so-called bucket platforms to lift utility personnel to service cable, telephone, and power lines. These voltage detection devices typically include an upwardly projecting mast or probe attached to the extensible boom that is capable of detecting the presence of high voltage lines within a specific range and of actuating an alarm to alert the boom or lift operator to the potential danger.

However, a significant number of preventable injuries and deaths result from accidental contact by power utility personnel with high voltage lines during manual set up and grounding of power poles in preparation for service and repairs. Thus, the present invention has been developed to be employed in combination with manually operated grounding clamps and/or other hand tools to provide an added measure of safety for electrical utility personnel when servicing high voltage power lines.

### SUMMARY OF THE INVENTION

Accordingly, the present invention is a high voltage detection device, which is adapted for use in combination with a manually operated grounding clamp or other hand tools used by electrical utility personnel when servicing high voltage power lines and other electrical equipment. In one embodiment of the present invention, the high voltage detection device is integrated into a manually operated grounding clamp that is attached to a grounding cable which is electrically connected to the frame of a so-called boom truck utilized to lift personnel upwardly to a position to perform maintenance operations on electrical power lines. The grounding clamp including the voltage detection device is manually attached to a so-called neutral line on the power pole to prevent accidental electrocution of a utility worker, who inadvertently comes into contact with high voltage flowing in a primary line during the power pole setup operation. The present invention is designed to detect the magnetic field generated by the flow of electrical current and to produce an audible alarm in advance of the impending contact with a source of high voltage to provide an extra measure of safety to utility personnel performing maintenance operations on power lines and other industrial equipment.

### BRIEF DESCRIPTION OF THE DRAWINGS

FIG. 1 is a diagrammatic elevational view of a utility boom truck whereon the present invention is utilized;

FIG. 2 is a perspective view of an adjustable grounding clamp for use on high voltage power lines;

FIG. 3 is a perspective view of an adjustable grounding clamp including the high voltage detection device of the present invention;

FIG. 4 is a schematic view of the high voltage detection device of the present invention showing the components thereof; and

FIG. 5 is a plan view of an alternative embodiment of the high voltage detection device of the present invention installed on a manual combination wrench.

### DETAILED DESCRIPTION OF THE PREFERRED EMBODIMENT

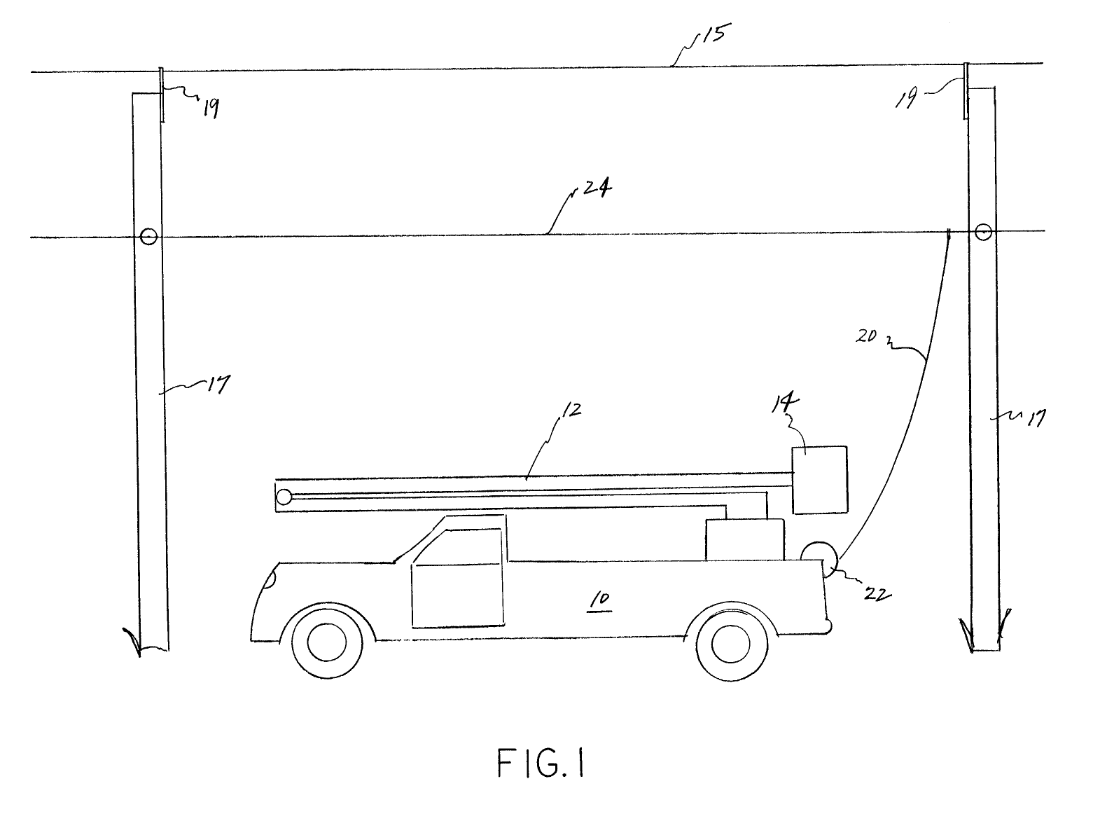

Prior to describing the structure and function of the present invention in detail, it may be beneficial to briefly review the safety procedures involved in preparing a high voltage power pole for maintenance operations. Under normal circumstances maintenance operations on a high voltage power line will be carried out by the use of a so-called boom truck, illustrated in FIG. 1 and indicated generally at 10. Such a boom truck 10 is typically outfitted with an extensible boom or mast 12 which carries a so-called bucket platform 14 wherein utility personnel are lifted upwardly to a convenient position to perform maintenance operations on electrical power lines.

A primary high voltage line 15 is normally installed at the uppermost portion of power poles 17 being mounted on horizontally disposed standards 19 and extending between poles 17. The poles 17 also support a so-called neutral line 24, which is typically attached to the poles 17 at a lower vertical elevation than the high voltage line 15 as shown in FIG. 1. The neutral line 24 is not insulated and functions as a ground path to prevent accidental electrocution of a utility worker, who inadvertently comes into contact with the high voltage flowing in the primary line 15.

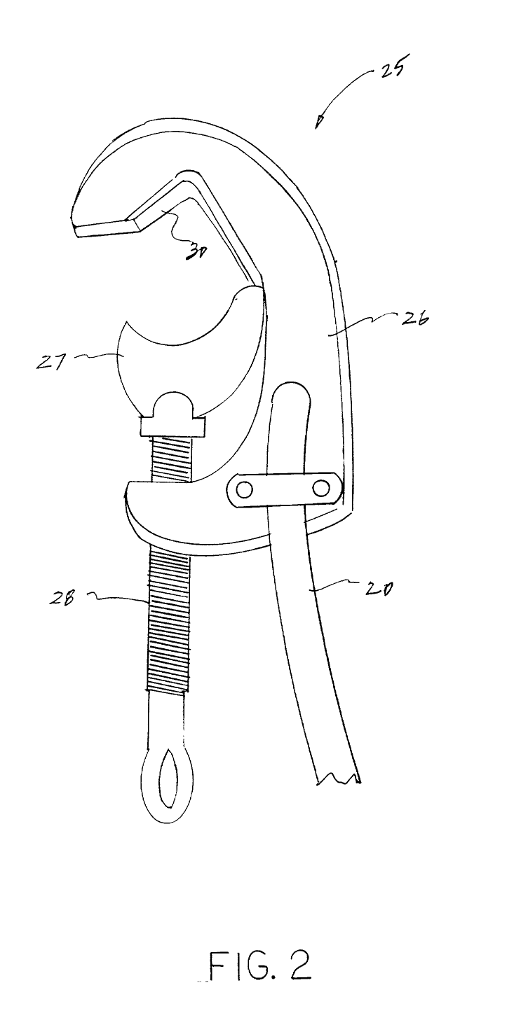

In order to ground the neutral line 24 prior to performing maintenance on a pole 17, an insulated grounding cable 20, which is electrically connected to the frame of the boom truck 10, is dispensed from a spool 22 or other similar device and mechanically attached to the neutral line 15. This connection is accomplished by the use of an adjustable grounding clamp, indicated generally at 25 and illustrated in FIG. 2.

Clamp 25 is comprised of a generally C-shaped body member 26 whereon the grounding cable 20 is electrically connected using suitable attaching hardware. Clamp 25 includes an adjustable jaw member 27 that engages the body member 26 by means of a threaded shaft 28 extending therethrough as shown. By advancing the shaft 28 into mating internal threads formed in a threaded aperture (not shown) in the body member 26, it will be appreciated that the neutral line 24 may be clamped between the jaw member 27 and anvil 30 formed in the body member 26 of the clamp in electrical connection with the neutral line 24.

Upon attachment of the clamp 25 to the neutral line 24, a ground circuit is created between the boom truck 10 and the neutral line 24. It will be understood by those skilled in the art that the boom truck 10 may also be electrically grounded by the use of outrigger legs (not shown), metallic rods, or other alternative ground apparatus to ensure a complete ground circuit from the neutral line 24.

Any number of commercially available grounding clamps of this type is suitable for this purpose. Since such adjustable grounding clamps are well known to those skilled in the art, further detailed discussion of the same is not deemed necessary.

Although this conventional grounding system, which utilizes the clamp 25 and grounding cable 20 described above, provides adequate protection to utility line workers once it has been installed, it has been determined that the set up of this grounding system and the installation process itself sometimes results in serious injuries and electrocution of utility personnel. This generally occurs when the clamp 25 is accidentally positioned by a utility line worker onto a primary high voltage line and/or when the grounding cable 20 inadvertently comes into contact with a primary high voltage line 15.

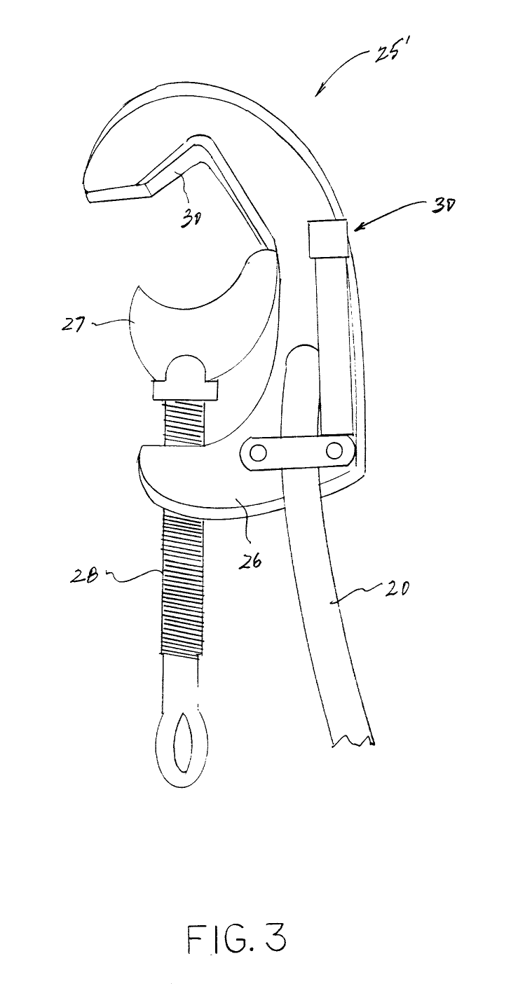

In order to prevent such accidents, the present invention has been developed and will now be described in detail. The present invention modifies the conventional grounding clamp 25 as described above by integrating a high voltage detection device, indicated generally at 30, to produce the modified clamp 25′ as shown in FIG. 3. The high voltage detection device 30 includes components providing a means for detecting a magnetic field generated by the flow of electrical current. Such components integrally form, for example, voltage detecting means including but not limited to those hereinafter described.

The voltage detection device 30 also includes elements providing a means for emitting sound to produce an audible alarm for utility personnel in advance of impending contact with the source of high voltage. Such elements integrally form, for example, sound emitting means including but not limited to those hereinafter described.

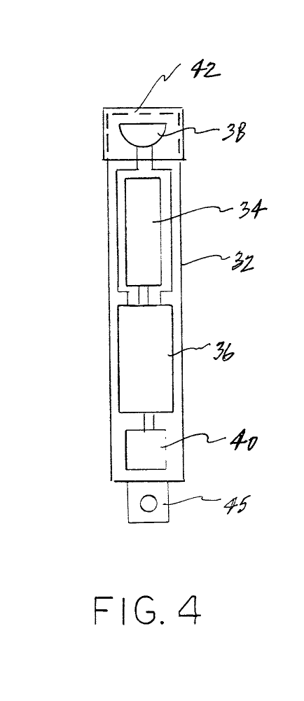

In the preferred embodiment the voltage detector 30 comprises a cylindrical housing 32 which is attachable to the clamp 25′ with the existing hardware that secures the grounding cable 20 to the clamp 25 by the use of a simple mounting bracket 45 as shown in FIG. 4.

As illustrated schematically in FIG. 4, the housing 32 contains a voltage sensor 34 of the type capable of detecting a magnetic field generated by the flow of electrical current in a specific voltage range for a given application. It will be understood that the voltage sensor 34 is designed to function with sensitivity that will detect high voltage within a relatively close range (i.e. 1 to 3 feet). The relatively close range of detection is intended to permit the utility worker to bring the clamp 25′ to within a safe distance from the neutral line 24, or other line attachment to determine whether it has high voltage flowing through it before making the manual connection.

If a magnetic field associated with high voltage is detected, the sensor 34 generates a signal that is transmitted to a microprocessor 36 electrically connected to the sensor 34 and contained within the housing 32. The microprocessor 36 is programmed to process the signal and to generate an alarm signal to actuate a miniature speaker 38, which produces an audible alarm for the utility lineman in advance of the impending contact.

A miniature battery 40 having sufficient power to provide the functions of the voltage detection device 30 is also contained within the housing 32 and is interconnected to the microprocessor 36 and other components by electrical circuitry. Further, the electrical circuitry may include various signal filtering and/or amplifying components to produce signals within a range of operating parameters.

The housing 32 is also provided with a sealed cap 42, which protects the electrical components of the voltage detection device 30 from atmospheric conditions. Such cap 42 may include a pattern of perforations (not shown) in proximity to the speaker 38 to facilitate the transmission of the audible alarm in a known manner.

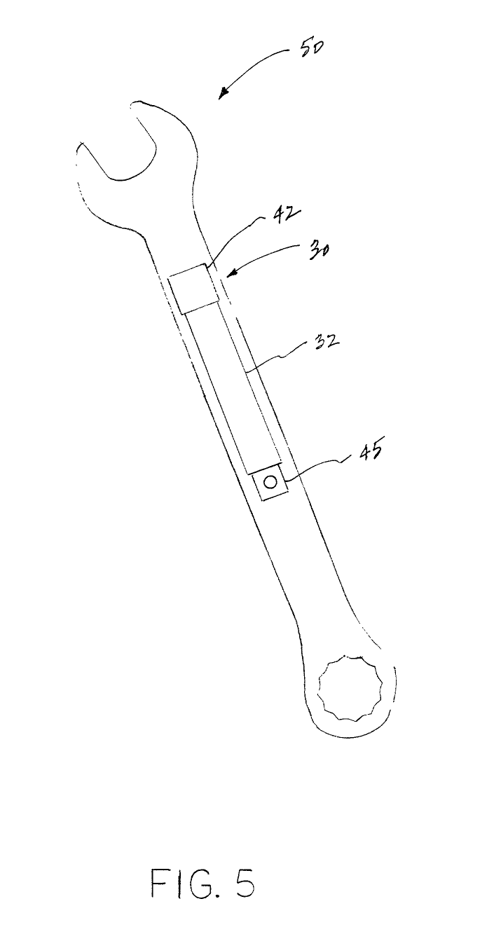

It will be understood that the present invention is also adaptable for use with various hand tools which may be utilized by electrical utility personnel and technicians in related trades to perform maintenance operations on high voltage power lines and other industrial equipment. Referring to FIG. 5 it will be appreciated that the present high voltage detection device 30 can be conveniently attached to conventional hand tools such as a combination wrench 50 by utilizing the mounting bracket 45 and suitable attaching hardware. In this manner an added measure of safety can be provided for electrical utility personnel and other service technicians performing maintenance operations on high voltage equipment.

Although not specifically illustrated in the drawings, it is understood that additional equipment and structural components will be provided as necessary, and that all of the components as described above are arranged and supported in an appropriate fashion to form a complete and operative system incorporating features of the present invention.

It is also understood that variations may be made in the present invention without departing from the spirit and scope of the invention. For example, the voltage detection device may be modified to be employed on various other hand tools commonly used by electrical, telephone and cable service personnel to avoid contact with electrical lines, which may be encountered in commercial and residential installations.

Although illustrative embodiments of the invention have been shown and described, a latitude of modification, change, and substitution is intended in the foregoing disclosure, and in certain instances some features of the invention will be employed without a corresponding use of other features.

What is claimed is:

1. A high voltage detection device for use in combination with a manually-operated grounding clamp and other hand tools, said device comprising:
a generally cylindrical housing including attaching means to provide mechanical attachment to said grounding clamp;
a voltage sensing means disposed within said housing capable of detecting a source of high voltage and of generating an output signal in response thereto;
a microprocessor disposed within said housing capable of processing said output signal and generating a warning signal in response thereto;
a sound emitting means disposed within said housing capable of receiving said warning signal and producing an audible alarm in response thereto; and
a power source disposed within said housing and being electrically interconnected to said sensing means, said microprocessor, and said sound emitting means by circuitry to provide the functions of said voltage detection device.

2. The high voltage detection device of claim 1 wherein said voltage sensing means includes a voltage sensor of the type capable of detecting a magnetic field produced by the flow of electrical current.

3. The high voltage detection device of claim 2 wherein said voltage sensor functions with sensitivity capable of detecting said magnetic field within a range of 1 to 3 feet.

4. The high voltage detection device of claim 1 wherein said sound emitting means includes a miniature audio speaker.

5. The high voltage detection device of claim 1 wherein said grounding clamp further comprises a generally C-shaped body member whereon a grounding cable is electrically connected.

6. The high voltage detection device of claim 5 wherein said grounding clamp includes at least one adjustable jaw member.

7. The high voltage detection device of claim 1 wherein said power source comprises a miniature battery.

8. An improved utility vehicle including an extensible mast having a bucket platform whereon utility personnel are lifted upwardly to perform maintenance operations on electrical power lines, said vehicle including a grounding cable having a grounding clamp electrically connected thereto for attachment to a neutral ground line to prevent accidental electrocution of said personnel, said improvements comprising:
a high voltage detecting means integrated with said clamp capable of producing an audible alarm in advance of impending contact with a source of high voltage.

9. The improved utility vehicle of claim 9 wherein said voltage detecting means further comprises:
a generally cylindrical housing including attaching means to provide mechanical attachment to said grounding clamp;
a voltage sensing means disposed within said housing capable of detecting a source of high voltage and of generating an output signal in response thereto;
a microprocessor disposed within said housing capable of processing said output signal and generating a warning signal in response thereto;
a sound emitting means disposed within said housing capable of receiving said warning signal and producing an audible alarm in response thereto; and
a power source disposed within said housing being electrically interconnected to said sensing means, said microprocessor, and said sound emitting means by circuitry to provide the functions of said voltage detecting means.

10. The improved utility vehicle of claim 10 wherein said voltage sensing means includes a voltage sensor of the type capable of detecting a magnetic field produced by the flow of electrical current.

11. The improved utility vehicle of claim 11 wherein said voltage sensor functions with sensitivity capable of detecting said magnetic field within a range of 1 to 3 feet.

12. The improved utility vehicle of claim 10 wherein said sound emitting means includes a miniature audio speaker.

13. The improved utility vehicle of claim 10 wherein said power source comprises a miniature battery.

14. The improved utility vehicle of claim 10 wherein said grounding clamp further comprises a generally C-shaped body member whereon a grounding cable is electrically connected.

15. The improved utility vehicle of claim 14 wherein said grounding clamp includes at least one adjustable jaw member.

16. An improved hand tool such as a combination wrench for use by utility personnel in performing maintenance operations on high voltage power lines and other industrial equipment, said improvements comprising:
a high voltage detecting means integrated with said tool capable of producing an audible alarm in advance of impending contact with a source of high voltage.

17. The improved hand tool of claim 16 wherein said voltage detecting means further comprises:
a generally cylindrical housing including attaching means to provide mechanical attachment to said grounding clamp;
a voltage sensing means disposed within said housing capable of detecting a source of high voltage and of generating an output signal in response thereto;
a microprocessor disposed within said housing capable of processing said output signal and generating a warning signal in response thereto;
a sound emitting means disposed within said housing capable of receiving said warning signal and producing an audible alarm in response thereto; and
a power source disposed within said housing and being electrically interconnected to said sensing means, said microprocessor, and said sound emitting means by circuitry to provide the functions of said voltage detection device.
